(19) United States
(12) Patent Application Publication
(10) Pub. No.: US 2025/0208192 A1
(43) Pub. Date: Jun. 26, 2025

(54) SOCKET SYSTEMS WITH INTEGRATED PARTIALLY-CONDUCTIVE SUBSTRATES AND METHODS OF USING THE SAME

(71) Applicant: Chiplytics Inc., Austin, TX (US)

(72) Inventors: Matthew Skeels, Austin, TX (US); Steven Dourmashkin, Seattle, WA (US); Tom Mikolyuk, Seattle, WA (US)

(21) Appl. No.: 18/393,548

(22) Filed: Dec. 21, 2023

(51) Int. Cl. G01R 31/28; G01R 1/04

(52) U.S. Cl. CPC G01R 31/2808; G01R 1/0416; G01R 1/0433; G01R 31/2863

(57) ABSTRACT

Implementations herein include socket systems and methods of using socket systems. Socket systems herein may comprise a housing configured to hold a printed circuit board, a clamp hingedly attached to the housing, and a soft partially-conductive substrate. A chip may be placed upon the soft partially-conductive substrate. By closing the clamp toward the housing, a uniform, gentle compressive force may be applied to the chip to effect contact between the chip's pins and the printed circuit board by selective compressing the soft partially-conductive substrate.

### BACKGROUND

Electronic engineering involves the study and application of electricity, electronics, and electromagnetism, including for the design and development of electronic circuits, devices, and systems. An aspect of electronic engineering involves the creation and improvement of printed circuit boards (PCBs), which are the backbone of modern electronic devices. PCBs are used to mechanically support and electrically connect electronic components using conductive pathways, or traces, etched from copper sheets laminated onto a non-conductive substrate.

Testing and programming of electronic components are a part of the electronic product development lifecycle. Testing ensures that electronic components and systems meet their specified performance criteria, are reliable, and are safe to use. Programming of microchips and devices allows the customization of their functions according to specific applications. Tools and equipment such as oscilloscopes, multimeters, and automated test equipment are commonly employed by engineers and technicians to diagnose issues, verify system behavior, and validate the functionality of electronic components and PCBs.

### SUMMARY

This Summary is intended to introduce, in an abbreviated form, various topics to be elaborated upon below in the Detailed Description. This Summary is not intended to identify key or essential aspects of the claimed invention. This Summary is similarly not intended for use as an aid in determining the scope of the claims.

A socket system may comprise a housing. The housing may include a base. The base may be configured to receive a printed circuit board. The printed circuit board may include a multitude of electrical contacts on a first side. A second side of the printed circuit board parallel to the first side may be disposed on the base. The printed circuit board may include a plurality of header pins. The header pins may be configured to electrically connect the printed circuit board to an electrical testing device or a programming device. The base may be configured for attachment to the electrical testing device or the programming device. The base is configured for mounting to a motherboard (e.g., a PCB serving as the central or primary circuit board within an electronic device, particularly computing devices). The header pins are configured to electrically connect the printed circuit board to the electrical testing device or the programming device via a cable. The housing may further include an alignment component. The alignment component may be integral with the base. In some implementations, the alignment component and the base may be monolithic.

The socket system may further comprise a clamp. The clamp may include a rigid cover. The rigid cover may be hingedly attached to the base. The rigid cover may be configured to rotate about the hinged attachment between a closed position of the clamp and an open position of the clamp. The clamp may further include a soft block. The soft block may be disposed on the rigid cover. The soft block may comprise rubber or foam.

The socket system may further comprise a soft partially-conductive substrate (e.g., a partially-conductive material). The soft partially-conductive substrate may be configured to be disposed on the first side of the printed circuit board such that, for example, the electrical contacts are covered by the soft partially-conductive substrate. The soft block may be configured to apply a compressive force to a chip disposed on the soft partially-conductive substrate when the clamp is in the closed position of the clamp. When the clamp is in the closed position, a portion of the chip may be abutted to the alignment component.

In some implementations, the base may further comprise a pressure sensor. The pressure sensor may be configured to sense a chip pressure, for example, resultant from the compressive force imparted on the chip by the soft block when the clamp is in the closed position.

In some implementations, the socket system may further comprise a camera. The camera may be configured to image the chip disposed on the soft partially-conductive substrate.

A method may comprise providing a socket system comprising a housing including a base and an alignment component, a clamp including a rigid cover and a soft block, and a soft partially-conductive substrate. The method may further comprise placing the chip on the soft partially-conductive substrate and closing the clamp. The method may further comprise determining an orientation of the chip relative to the printed circuit board. The method may further comprise testing the chip.

### BRIEF DESCRIPTION OF THE FIGURES

For a fuller understanding of the nature and objects of the disclosure, reference should be made to the following detailed description taken in conjunction with the accompanying drawings, in which:

FIG. 1A illustrates a socket system, according to one or more implementations herein;

FIG. 1B illustrates a printed circuit board including a grid-array of contacts, according to one or more implementations herein;

FIG. 1C illustrates a soft partially-conductive substrate, according to one or more implementations herein;

FIG. 2 illustrates an alignment modality implementing a camera, according to one or more implementations herein;

FIG. 3 illustrates a chip, according to one or more implementations herein;

FIG. 4 illustrates an alignment modality implementing a pressure sensor, according to one or more implementations herein;

FIG. 5 illustrates an example placement of a chip within a socket system, according to one or more implementations herein; and

FIG. 6 is a flowchart illustrating a method of fitting a chip to a socket, according to one or more implementations herein.

### DETAILED DESCRIPTION

It is to be understood that the invention is not limited in its application to the details of construction and the arrangements of components and/or method steps set forth in the following description or illustrated in the drawings, and phraseology and terminology used herein is for the purpose of description and should not be regarded as limiting. The invention is capable of other embodiments and of being practiced or being carried out in various ways. Accordingly, other aspects, advantages, and modifications will be apparent to those skilled in the art to which the invention pertains, and these aspects and modifications are within the scope of the invention, which is limited only by the appended claims.

Implementations herein include socket systems and methods of using the same. Socket systems herein may be configured to provide an electrical interface between a chip (e.g., a semiconductor chip) and a printed circuit board (PCB). This system may comprise of a housing that receives the PCB, a clamp mechanism capable of moving between an open position and a closed position to secure the chip in place, and a compressible element such as a soft block that applies pressure to the chip. The system may also include a soft, partially-conductive substrate that may be placed between the chip and the PCB to facilitate an electrical connection through a conductive filament grid within the substrate. The socket system may be further characterized by alignment features that ensure the chip may be precisely positioned relative to the PCB's contacts, or may incorporate a pressure sensing mechanism to monitor the force applied to the chip. The system may be configured to provide a reliable and temporary electrical connection for purposes such as testing, programming, or interfacing the chip with other electronic components or systems.

An electrical testing device may include an apparatus or setup employed to evaluate the electrical properties, performance, or functionality of electronic components, circuits, or systems. This may include, but may be not limited to, multimeters, oscilloscopes, signal generators, network analyzers, logic analyzers, in-circuit test equipment, automated test equipment, and specialized diagnostic fixtures designed to apply test signals to a device under test and measure its responses. These devices can be used to perform a variety of tests such as continuity checks, resistance measurements, voltage drop analysis, signal tracing, and functional testing of the electronic component or circuit. The electrical testing device may also encompass software and hardware elements required to execute test sequences, record results, and analyze data for quality control, fault diagnosis, or design verification purposes. In the context of the described system, the electrical testing device would interface with the socket system and the PCB to perform these assessments on the chip that may be being tested.

A programming device may include an apparatus equipped with the necessary hardware and software interfaces designed to write, modify, or upload firmware or software onto a chip or integrated circuit. This device can facilitate the transfer of data and instructions to the chip, which may be necessary for its initial configuration or for updating its operational parameters. It may include, but may be not limited to, equipment such as in-circuit programmers, onboard programming systems, or external programming units that connect to the chip through the socket system described herein. A programming device may also offer diagnostic functions to verify the integrity of the programming process, ensuring that the chip functions according to its design specifications once installed in its intended operational environment. Such a device can be standalone or integrated into a larger system, such as a computer or industrial control system, and may be capable of interfacing with various chip architectures and communication protocols.

Electronics manufacturing and testing faces ongoing challenges in effectively and safely interfacing various components, such as microchips, with PCBs during critical processes including electrical testing and programming. A frequent issue encountered may be the need for a reliable, yet delicate, connection that allows for accurate data transmission without causing damage to the sensitive elements of the chip or the PCB. The industry would be advanced by a solution that addresses the difficulties in maintaining consistent contact pressure, precise alignment of the chip to the PCB contacts, and the ability to accommodate variations in chip and PCB sizes. Furthermore, the ability to monitor the connection process visually and ensure that the correct pressure may be applied may be also of significant concern, as may be the need to quickly and efficiently interface with various external testing and programming devices.

A conventional solution may include a bed of nails tester, which employs a series of pins configured to make contact with various test points on a PCB for electrical testing. A bed of nails tester may be a traditional device used for testing the electrical properties of a circuit board or electronic component. It consists of an array of small, spring-loaded pogo pins—each functioning as a test probe—that are arranged to make contact with various test points on the circuit board. When a board may be pressed against these pins, they ensure a secure and precise connection to the designated test pads or vias on the board. The tester may be typically connected to a measurement system that can apply signals and measure responses at each pin, thereby verifying the proper operation of the circuit or identifying faults.

The technical workings of this system involve a programmable interface that can send specific electrical signals through individual pogo pins. These signals can simulate the inputs that a functioning circuit would normally receive during operation. The system then measures the output signals from the circuit, which are relayed back through the pogo pins, to assess whether the circuit may be functioning as expected. The bed of nails tester can check for opens, shorts, resistance, capacitance, and other electrical characteristics, providing a comprehensive evaluation of the circuit's performance.

Traditional bed of nails testers face a range of technical challenges that can limit their effectiveness. One notable issue may be the difficulty in aligning and maintaining contact with an increasing number of miniaturized and densely packed test points on modern electronic circuit boards, which can lead to unreliable test results. Additionally, the mechanical pressure applied by the pins may damage the delicate components or circuits, particularly in the case of repeated testing. The rigid nature of these testers also presents a lack of flexibility when it comes to testing different board designs without creating a new fixture, leading to increased time and cost for fixture fabrication.

Conventional spring-loaded pogo pins designed to create a temporary yet secure electrical connection between two electronic components. Pogo pins, commonly used for establishing temporary electrical connections in various electronic devices, consist of a small spring contained within a cylindrical tube. This arrangement allows for a controlled and consistent pressure to be exerted upon contact, thereby ensuring reliable electrical connectivity. The typical construction of a pogo pin includes a plunger that moves freely within the barrel, which houses the spring. When the pin makes contact with a conductive surface, the plunger compresses the spring, creating a physical and electrical connection. Upon removal of the pressure, the spring's elasticity returns the plunger to its original position. This design allows for numerous cycles of connection and disconnection without significant degradation of performance, making pogo pins suitable for applications where repeated connections are required, such as in charging docks, test equipment, and programming interfaces. The materials and coatings used for the conductive elements of the pogo pin are selected to optimize electrical conductivity and minimize resistance, while also providing durability against wear and corrosion.

Conventional spring-loaded pogo pin connectors exhibit several technical shortcomings that may affect performance and durability. For instance, these connectors can suffer from inconsistent electrical contact due to debris accumulation or misalignment, particularly in environments where they are subjected to frequent connection and disconnection cycles. Additionally, the reliance on mechanical springs to maintain contact pressure can lead to wear and eventual failure of the spring mechanism, potentially resulting in decreased contact force over time. This degradation can compromise the integrity of the electrical connection, leading to intermittent signals or power loss. Furthermore, the small size and delicate structure of these components can make them susceptible to damage during handling or when subjected to excessive insertion forces, thus affecting their longevity and reliability in various applications.

A further conventional solution may include a clamshell socket arrangement for the secure attachment and electrical connection of a semiconductor device to a printed circuit board. Typically, this solution comprises two hinged halves that encase the electrical components necessary for establishing a connection. Upon closure, the halves form a protective shell around the electrical contacts, which are aligned to interface with corresponding contacts on the device or power supply. A locking mechanism may be often integrated to ensure that the socket remains closed, thus maintaining a consistent and stable connection.

The technical workings of this solution involve the precise arrangement of conductive elements within the clamshell socket that, when engaged, create an electrical pathway from the power source to the device. These elements are designed to withstand repeated use and to provide a reliable connection that minimizes resistance and electrical loss. The interior of the clamshell socket may also include features to guide the insertion of a plug or device, ensuring proper alignment and reducing the likelihood of damage to the contacts during connection and disconnection cycles.

The conventional clamshell socket solutions exhibit several technical limitations. These sockets, while designed to secure an electrical component, can lead to suboptimal connection quality due to inconsistent clamping force, which may compromise the electrical integrity of the connection. Furthermore, the mechanical complexity of these sockets often results in increased manufacturing costs and challenges in miniaturization, which are significant drawbacks in an industry where space-saving and cost efficiency are highly sought after. Additionally, the wear and tear from repeated use can degrade the contact points, leading to increased electrical resistance and potential failure of the electrical component, thereby reducing the reliability and longevity of the device in which they are installed.

Implementations herein provide improved socket systems designed to enable a chip to reliably interface with a PCB for purposes such as electrical testing or programming.

The socket system may include a housing with a base onto which the PCB may be mounted, with the PCB's electrical contacts accessible on one side. A clamp with a hingedly attached rigid cover can move between open and closed positions. A soft block may be positioned on this cover. There may be also a soft partially-conductive substrate designed to be placed on the PCB over the electrical contacts. This substrate incorporates a conductive filament grid embedded in a non-conductive material. When the clamp may be closed, the soft block may exert a compressive force on a chip situated on the soft substrate, ensuring electrical connection between the chip and the PCB's contacts.

Further aspects to the system may include an alignment component that may be integral with the base, potentially formed as a single, monolithic piece. This alignment component helps position the chip properly when the clamp may be closed. Additionally, the base may include a pressure sensor to detect the force applied to the chip, ensuring proper contact without damage.

To facilitate the observation and alignment of the chip, the system may in some implementations be equipped with a camera. The PCB itself may have header pins for establishing electrical connections to external devices such as test or programming equipment, which can be direct or via a cable.

The soft block within the clamp may comprise materials like rubber or foam to provide the right balance of compressive force and cushioning. The base of the system may be versatile, being designed for attachment to an electrical testing device, a programming device, or even for mounting to a motherboard.

The socket system may integrate several features to provide a secure and precise connection between a chip and a PCB for testing or programming purposes, with considerations for alignment, pressure monitoring, and ease of use.

Implementations herein include a soft, partially conductive substrate with an embedded conductive filament grid, and a clamp mechanism with an attached soft block that applies compressive force to ensure a secure electrical connection without damaging the chip.

The substrate's design allows for a uniform and gentle contact between the chip and the PCB, accommodating for surface irregularities and mitigating the risk of damage due to excessive pressure. The integration of a pressure sensor within the base of the system provides real-time feedback to ensure optimal force may be applied, further enhancing the safety and reliability of the connection.

An alignment component, for example, integrated with the base, aids in the precise placement of the chip, reducing the likelihood of misalignment and the resulting connection errors. The incorporation of a camera or pressure sensor can assist users in more accurately aligning the chip with the PCB's contacts.

Implementations herein offer significant benefits over existing technologies by simplifying the process of establishing a secure connection between a chip and a PCB. This results in increased efficiency in testing and programming operations. The design may be versatile and may be adapted for different chips and PCBs, making it a universal tool for various applications. The system's potential for modularity and adaptability, along with features aimed at enhancing precision and safety, represent a meaningful advancement in the field of electronic component testing and programming.

The described system provides a distinct approach to interfacing chips with a PCB compared to conventional solutions. Traditional bed of nails testers use an array of spring-loaded pins to make contact with the PCB, which can be less adaptable to various chip sizes and configurations and may cause damage to the PCB or the chip due to the localized pressure of the pins. In contrast, the present system uses a soft, partially-conductive substrate with an embedded conductive filament grid that distributes the force more evenly, mitigating the risk of damage to delicate components. Unlike spring-loaded pogo pins, which require precise alignment and can wear out due to their mechanical nature, the described system's alignment component and soft block provide a more durable and forgiving means of alignment and connection. Clamshell sockets typically involve a mechanical fixture that clamps a device into place, often requiring significant force and potentially causing misalignment or damage. The system at hand, however, offers a hinged clamp mechanism with a soft block that applies a gentle yet firm pressure, ensuring a reliable connection without the drawbacks of conventional clamshell designs. This approach allows for a more adaptable, gentle, and reliable method of interfacing chips with a PCB for various applications such as testing and programming.

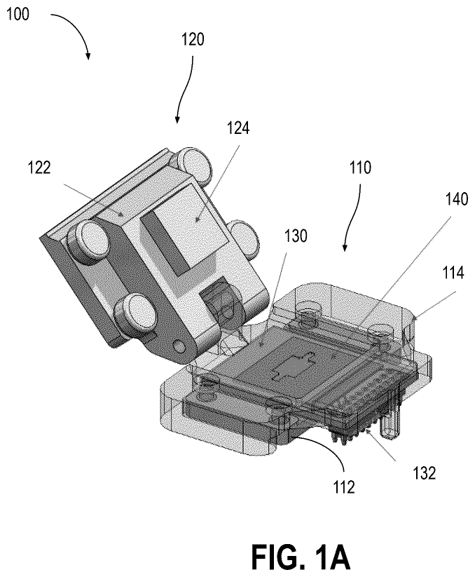

FIG. 1A illustrates a socket system 100, according to one or more implementations herein. The socket system 100 may be used, for example, for electronics testing and programming.

The socket system 100 may comprise a housing 110. The housing 110 may be a structure that provides a supportive framework for the socket system. The housing 110 may encompass physical boundaries and support mechanisms that maintain the relative positioning of the system 100's components. It may include a base upon which a PCB 130 can be mounted or affixed, with provisions for access to the PCB 130's electrical contacts. The housing 110 may also incorporate features for the attachment and operation of a clamp mechanism, which can exert a controlled force on a chip when placed within the system. Additionally, the housing 110 may contain alignment features to facilitate the correct placement of the chip in relation to the PCB 130's electrical contacts, and may be constructed of materials that offer durability and stability while accommodating the integration of additional components such as cameras, sensors, or connectors. The housing 110 thus may serve as the foundation of the socket system 100, ensuring that all other components maintain their correct positions and functions during the operation of interfacing a chip with a PCB 130.

The housing 110 may include a base 112. The base 112 may be a component of the socket system 100 upon which other elements are mounted or integrated. The base 112 may provide structural support and may include features for aligning and securing the PCB 130 in a fixed position. It may also contain fixtures or guides for positioning the soft, partially-conductive substrate 140 and for proper placement of the chip prior to engagement by the clamp 120. The base 112 may be fabricated from materials that offer rigidity and durability, such as metals, plastics, or composites, and may have connectors or interfaces for electrical communication with external devices. Additionally, the base 112 may serve as a platform for incorporating additional functionalities, such as pressure sensing capabilities, or it may have provisions for attachment to other equipment, ensuring that the socket system 100 remains stable during the testing or programming of the chip.

FIG. 1B illustrates a printed circuit board 130 including a grid-array of contacts, according to one or more implementations herein. Contacts may be conductive and regularly-spaced. The printed circuit board 130 may include a multitude of electrical contacts on a first side. A second side of the printed circuit board 130 parallel to the first side may be disposed on the base 112. The printed circuit board 130 may include a plurality of header pins 132 (depicted in FIG. 1A). The header pins 132 may be configured to electrically connect the printed circuit board 130 to an electrical testing device or a programming device.

Returning to FIG. 1A, the base 112 may be configured for attachment to the electrical testing device or the programming device. The base 112 may, in some implementations, be configured for mounting to a motherboard. The header pins 132 may be configured to electrically connect the printed circuit board 130 to the electrical testing device or the programming device via a cable. The header pins 132 may include protruding conductive pins that are typically mounted on the PCB 130 or the base 112 of the socket system 100. These pins 132 may be arranged in a manner that allows them to interface with corresponding receptacles or connectors, thereby establishing an electrical connection. The header pins 132 may serve as a conduit for electrical signals between the PCB and external devices, such as test equipment, programming modules, or other circuitry required for the operation or assessment of the chip seated within the socket system. The design and configuration of the header pins may be tailored to match the specific requirements of the PCB 130 and the external connections needed for its intended application.

The PCB 130 may include a substrate used in electronics to mechanically support and electrically connect electronic components using conductive pathways, tracks or signal traces etched from copper sheets laminated onto a non-conductive substrate. It may include multiple layers of copper sheets separated by insulating materials. The PCB 130 may be utilized for both through-hole technology components and surface-mounted devices. The board itself can be of various shapes and sizes and may be designed to fit within electronic devices, ranging from small handheld units to large, complex industrial machinery. The electrical contacts relevant to this system may be located on the surface of the PCB 130 and may be arranged to interface with integrated circuits or other electronic components.

The housing 110 may further include an alignment component 114. The alignment component 114 may be integral with the base 112. In some implementations, the alignment component 114 and the base 112 may be monolithic. The alignment component 114 may include a feature or mechanism associated with the housing of the socket system that facilitates the correct positioning of a chip relative to the PCB. The alignment component 114 may serve to guide, position, and maintain the chip in a precise location such that, when the clamp may be closed, electrical contacts on the chip are properly aligned with corresponding contacts on the PCB. The alignment component 114 may be realized as a series of pins, protrusions, recesses, or a contoured surface designed to mate with complementary structures on the chip or a chip carrier. It may be integrated into the base of the housing or be a separate part that may be attachable to the housing. The alignment component 114 may also include visual indicators or be constructed to work in conjunction with imaging systems to aid in manual or automated alignment processes.

The socket system 100 may further comprise a clamp 120. The clamp 120 may include a mechanical assembly that may be capable of moving between an open position and a closed position and may be designed to apply a controlled amount of pressure to objects placed between its components. Within the context of the socket system 100, the clamp 120 may comprise a rigid cover 122, which may be integral with or attached to the housing 110 that supports the PCB 130. The rigid cover 122 may be hingedly connected to the base 112, allowing it to pivot towards the base 112 to effect the closed position and away from the base to effect the open position. The clamp 120 may also include a mechanism, such as a lever, a screw, a spring, or other suitable actuators, to facilitate the controlled movement and to enable a user to apply sufficient pressure to maintain the chip in contact with the soft, partially-conductive substrate, and thereby ensure reliable electrical connectivity with the PCB 130's contacts. The pressure applied by the clamp may be finely adjustable and measurable, for example, using integrated sensors, to prevent damage to the chip and the PCB 130 while maintaining a strong electrical connection.

In embodiments of the invention, the rigid cover 122 may be pressed down vertically using a linear stage.

The clamp 120 may include a rigid cover 122. The rigid cover 122 may be hingedly attached to the base 112. The rigid cover 122 may be configured to rotate about the hinged attachment between a closed position of the clamp and an open position of the clamp. The rigid cover 122 may be mechanically coupled to the clamp 120 and capable of moving in relation to the base 112. The rigid cover 122 may be constructed from a material with sufficient rigidity to withstand the forces applied during the clamping operation without significant deformation. It serves to evenly distribute the compressive force exerted by the soft block 124 onto the chip when the clamp 120 may be in the closed position, thereby facilitating a uniform electrical connection between the chip and the PCB 130's contacts. The rigid cover 122 may also incorporate features such as apertures or integrated lenses to allow for the passage of light or alignment mechanisms that may be used in conjunction with a camera system for precise positioning of the chip on the soft partially-conductive substrate 140. The rigid cover 122 may be designed to maintain its shape under normal operational conditions and to ensure the consistent and reliable functioning of the socket system 100.

The hinged attachment of the rigid cover 122 to the base 112 may include a mechanism by which two or more parts are joined together, allowing for rotational movement along a single axis. This attachment can be realized through various mechanisms, such as a pin hinge, a living hinge made from a flexible material, or a complex hinge incorporating a spring or damping element. In the context of the socket system 100, a hinged attachment enables the rigid cover 122 to move relative to the base 112 from an open position, granting access to the area where the chip and PCB 130 are situated, to a closed position, where the chip may be pressed against the PCB 130 for electrical connection. This hinged attachment may be designed to ensure consistent alignment and pressure application during repeated opening and closing cycles.

The closed position may refer to a state or configuration in which the clamp 120 and its attached rigid cover 122 are positioned such that the soft block 124 exerts a downward force upon the chip, which in turn presses the chip against the soft partially-conductive substrate on the PCB 130. This results in the conductive filament grid making electrical contact with the corresponding contacts on the PCB 130, thus establishing an electrical connection between the chip and the PCB 130 for the purpose of testing, programming, or other interfacing activities. The closed position may be achieved when the clamp 120 may have been actuated to a point where the required compressive force may be met, as, for example, indicated by a pressure sensor, and may be maintained securely to ensure a stable and reliable connection throughout the duration of the interfacing process.

The open position may refer to state or configuration of the clamp 120 wherein the hingedly attached rigid cover 122 may be positioned away from the base, allowing unobstructed access to the area of the base where the PCB 130 may be to be mounted, as well as to the soft partially-conductive substrate 140 when it may be in place. In the open position, the chip to be tested or programmed can be easily positioned on the substrate 140, and the PCB 130 can be freely placed, removed, or adjusted without interference from the cover of the clamp 120. The open position may be thus a preparatory setting that facilitates the arrangement of the chip and the PCB 130 prior to engagement and the establishment of electrical connections.

The clamp 120 may further include a soft block 124. The soft block 124 may be disposed on the rigid cover 122. The material composition of the soft block 124 can vary and may include elastomers, rubber, foam, or other compressible materials with suitable properties. The soft block 124 may also be designed in various shapes and sizes to accommodate different chip configurations and sizes. It functions as an intermediary between a rigid cover 122, which may be part of a clamping mechanism, and the chip itself. When the clamp 120 may be engaged, the soft block 124 compresses and translates the force from the rigid cover 122 to the chip, facilitating an effective electrical contact with the underlying soft partially-conductive substrate 140, which in turn interfaces with the contacts on the PCB 130.

The soft block 124 may comprise rubber, for example, any elastomeric material that exhibits flexibility, elasticity, and resilience, suitable for creating a compressive force while providing cushioning properties. This may include natural rubber derived from latex, as well as synthetic rubbers such as butadiene rubber, styrene-butadiene rubber, nitrile rubber, ethylene propylene diene monomer (M-class) rubber, and silicone rubber. These materials can be chosen based on their ability to deform under pressure and return to their original shape after the removal of the force, ensuring the necessary contact between the chip and the electrical contacts on the PCB 130 without causing damage due to excessive pressure. The specific type of rubber used in the system may be selected based on factors such as the operating temperature range, electrical properties, chemical resistance, and the mechanical properties required for the specific application of the socket system 100.

The soft block 124 may comprise foam, for example, a substance that may be formed by trapping pockets of gas in a liquid or solid. In the context of this socket system, “foam” may denote a lightweight, porous material that may be capable of exerting a controlled compressive force when compressed. This material may have various levels of rigidity and compressibility that can be selected based on the specific requirements of the system, such as the desired pressure distribution and the degree of cushioning needed to protect the integrity of the chip and the electrical contacts during the testing or programming process. The foam used in the soft block of the clamp may be an elastomeric polymer with open or closed cells, which can deform under pressure to create an even interface between the chip and the conductive substrate. This deformation allows for the accommodation of any minor variances in the height of the electrical contacts or the chip surface, thereby ensuring a consistent connection without applying excessive force that could damage the delicate components. This foam material may also have properties that resist chemical degradation, thermal breakdown, and physical wear, maintaining its functionality over repeated use cycles. Furthermore, the foam may be selected for its antistatic properties, reducing the risk of static discharge that could potentially damage sensitive electronic components during handling.

The soft block 124 may be configured to apply a compressive force to a chip disposed on the soft partially-conductive substrate 140 when the clamp 120 is in the closed position of the clamp 120. The compressive force may include, for example, downward pressure applied by the soft block through the clamp mechanism onto the chip when the cover may be in the closed position. This force may be intended to press the chip onto the soft, partially-conductive substrate 140 and ensure a reliable electrical connection between the chip's contact points and the corresponding contacts on the PCB 130 without causing damage to the chip or PCB 130. The magnitude of this force may be carefully controlled to achieve optimal contact pressure and may be generally uniform across the surface area of the chip to maintain consistent contact quality for all pins or contact points involved.

The socket system 100 may further comprise a soft partially-conductive substrate 140. FIG. 1C illustrates a soft partially-conductive substrate 140, according to one or more implementations herein. Soft partially-conductive substrate 140 may comprise a grid of vertical conductive filaments in a substrate of soft non-conductive material. The soft partially-conductive substrate 140 may include a material layer that exhibits a degree of flexibility and compressibility suitable for conforming to the surface irregularities of a PCB and a chip. This substrate 140 may be fabricated from a matrix of non-conductive elastomeric or polymer-based material within which a network of conductive filaments may be embedded. The conductive filaments may be arranged in a grid or other pattern that allows for the establishment of electrical connections across the substrate. The material properties of the substrate 140 allow it to act as an intermediary conducting layer that can conform to both the chip and PCB surfaces, thereby enabling the establishment of reliable electrical connections between the chip's terminals and the corresponding contacts on the PCB 130 when pressure may be applied. The soft nature of the substrate 140 ensures that the pressure exerted does not damage the delicate structures of the chip or PCB 130, while its partial conductivity allows for selective electrical connection without the risk of short-circuiting adjacent contacts. The conductive filaments in the soft partially-conductive substrate 140 may include slender thread-like conductive materials that are capable of establishing an electrical connection. These filaments may be composed of metals, metal alloys, conductive polymers, or any combination thereof that allows for the conduction of electrical signals. In the context of the described system, these conductive filaments are embedded within a non-conductive or less conductive matrix, forming a soft substrate that lies between the chip and the PCB 130 contacts. The conductive filaments are arranged in a manner such that when pressure may be applied, they create a reliable and controlled electrical interface between the contact points on the chip and corresponding contacts on the PCB 130 without causing damage to the delicate structures of the chip or the PCB 130. The configuration of the conductive filaments may be optimized for uniform current distribution and signal integrity while also ensuring that the mechanical pressure applied may be evenly distributed across the contact points.

A non-conductive material may include any substance or composite that does not allow the flow of electrical current under the conditions typically encountered in the operation of the described system. This material may be chosen based on its electrical insulating properties to prevent unintended electrical pathways between the conductive elements of the chip and the PCB 130. The non-conductive material may be part of the soft, partially-conductive substrate 140 and may serve as a matrix in which the conductive filament grid may be embedded. The selection of the non-conductive material may take into account factors such as its compressibility, thermal stability, and chemical resistance to ensure that it maintains its insulating properties throughout the intended use of the socket system. It may also be chosen for its durability and ability to be manufactured with the precision necessary to maintain the desired spacing and isolation of the conductive elements within the substrate. Examples of non-conductive materials suitable for use in this context may include but are not limited to, various polymers, ceramics, glass, resins, or composite materials specifically formulated to have low electrical conductivity.

The soft partially-conductive substrate 140 may be configured to be disposed on the first side of the printed circuit board such that, for example, the electrical contacts are covered by the soft partially-conductive substrate 140.

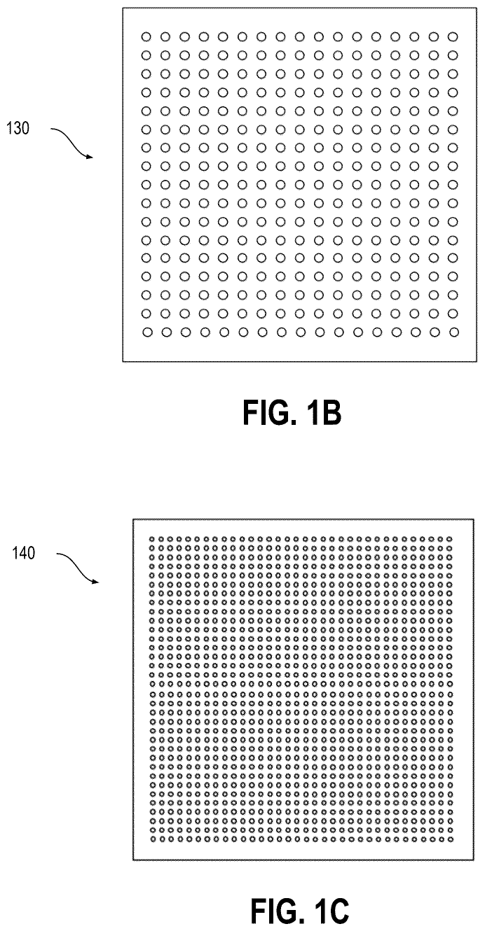

FIG. 2 illustrates an alignment modality implementing a camera 202, according to one or more implementations herein. Camera 202 may be pointing directly down onto a socket system 201 and able to view the orientation of the chip on the soft, partially conductive substrate.

Camera 202 may be configured to image chip disposed on the soft partially-conductive substrate. Camera 202 may include any imaging device capable of capturing visual information for the purpose of monitoring, alignment, or inspection. This may include but may be not limited to digital cameras, optical sensors, charge-coupled devices (CCD), complementary metal-oxide-semiconductor (CMOS) sensors, or any other type of electronic device that can produce an image or video feed. The camera can be integrated into the system to provide a live view of the chip and the PCB to assist in precise placement of the chip onto the conductive filament grid of the soft substrate. Camera 202's output can be displayed, for example, on a monitor or interface to aid an operator in the alignment process, or it can be interfaced with a computer system for automated alignment via image processing algorithms. Camera 202 may be adjustable and may include features such as zoom, focus, and variable illumination to enhance image quality and facilitate the accurate and efficient alignment of the chip with the PCB's contacts.

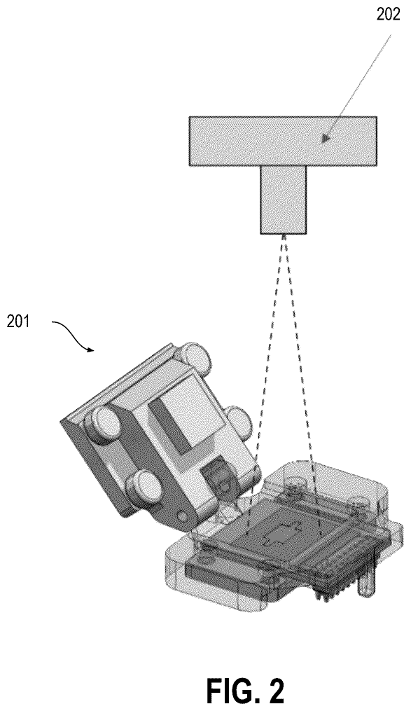

FIG. 3 illustrates a chip 300, according to one or more implementations herein. Chip 300 may include any type of integrated circuit or semiconductor device which may be designed to perform electronic functions. This may include microprocessors, microcontrollers, memory chips such as RAM, ROM, EEPROM, flash memory, or any other type of electronic module that can be interfaced with a PCB. The chip may be of various form factors, including but not limited to dual in-line package (DIP), surface mount device (SMD), ball grid array (BGA), or chip scale package (CSP). The chip may contain electronic circuits that can be programmed, tested, and utilized for various applications across different industries, including but not limited to computing, telecommunications, consumer electronics, automotive systems, and industrial automation.

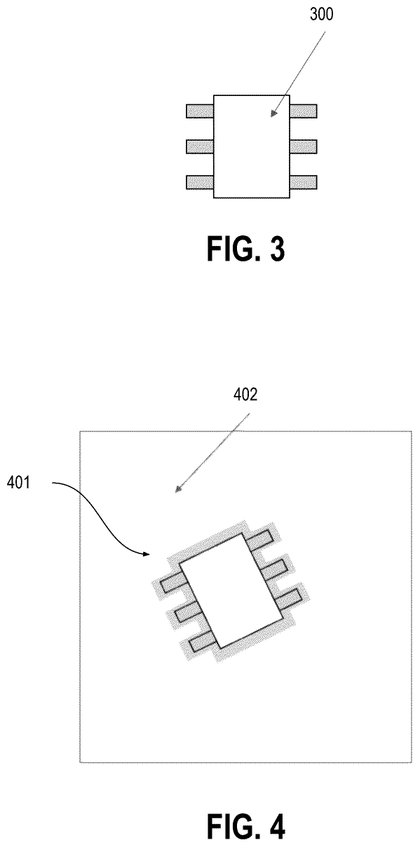

FIG. 4 illustrates an alignment modality implementing a pressure sensor 402, according to one or more implementations herein. Pressure sensor 402 may be used to determine an orientation of a chip 401 within a socket.

Pressure sensor 402 may be configured to sense a chip pressure, for example, resultant from the compressive force imparted on chip 401 by the soft block when the clamp is in the closed position. Pressure sensor 402 may include a device or component capable of detecting the magnitude of force exerted upon chip 401 when it may be clamped onto the PCB via the socket system. Pressure sensor 402 may function by converting the physical force into an electrical signal, which can be quantified and monitored to ensure the chip may be subjected to an appropriate level of pressure. This device may be integrated into the base or other parts of the clamp mechanism to provide real-time feedback on the force applied. It may be based on various technologies including, but not limited to, piezoelectric, capacitive, strain gauge, or semiconductor sensors. Pressure sensor 402 may be calibrated to measure a range of forces suitable for making reliable electrical connections without causing physical damage to the chip or the PCB. The information provided by the pressure sensor may be utilized to adjust the clamp's pressure, either manually or automatically, to maintain optimal contact between the chip and the PCB during testing or programming operations.

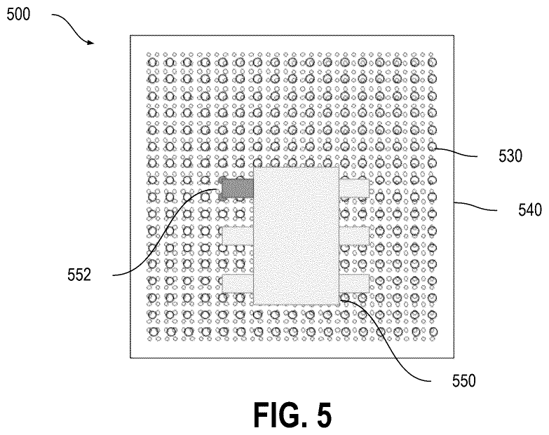

FIG. 5 illustrates an example placement of a chip 550 within a socket system 500, according to one or more implementations herein. Socket system 500 may thus present functionality as a universal socket. Chip 550 (e.g., similar to chip 300) may be disposed atop a soft partially-conductive substrate 540 (e.g., similar to the soft partially-conductive substrate 140), which may itself be atop a PCB 530 (e.g., similar to the PCB 130). Optionally, an alignment pin 552 may be designated on chip 550, which may be used for aligning the chip 550 on the soft partially-conductive substrate 540.

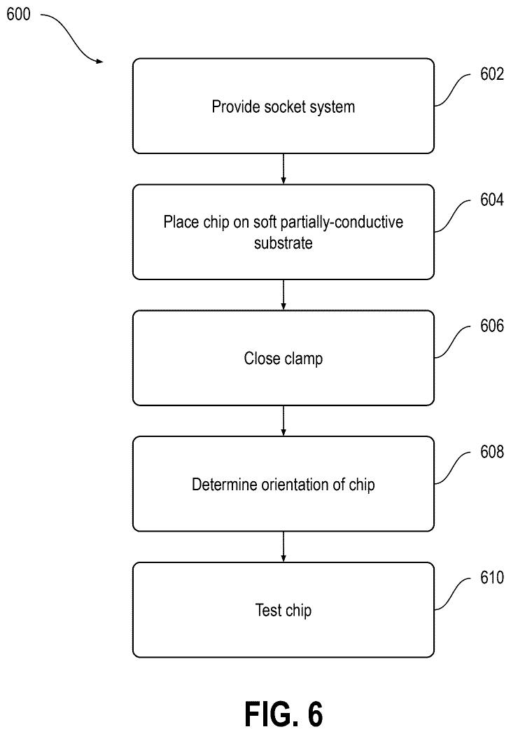

FIG. 6 is a flowchart illustrating a method 600 of fitting a chip to a socket, according to one or more implementations herein. In some implementations, one or more operations illustrated in FIG. 6 may be performed by a one or more of the devices illustrated in FIGS. 1-5. Additionally, or alternatively, one or more operations illustrated in FIG. 6 may be performed by one or more other components.

An operation 602 may include providing a socket system, and may be performed alone or in combination with one or more other operations depicted in FIG. 6.

An operation 604 may include placing a chip on the soft partially-conductive substrate of the socket system, and may be performed alone or in combination with one or more other operations depicted in FIG. 6.

An operation 606 may include closing the clamp of the socket system, and may be performed alone or in combination with one or more other operations depicted in FIG. 6.

An operation 608 may include determining an orientation of the chip relative to the printed circuit board of the socket system, and may be performed alone or in combination with one or more other operations depicted in FIG. 6.

An operation 610 may include testing the chip, and may be performed alone or in combination with one or more other operations depicted in FIG. 6.

Although FIG. 6 depicts example method 600 and operations thereof, in some implementations, a method illustrated herein may include additional operations, fewer operations, differently arranged operations, or different operations than the operations depicted in FIG. 6. Moreover, or in the alternative, two or more of the operations depicted in FIG. 6 may be performed at least partially in parallel.

Various characteristics, advantages, implementations, embodiments, and/or examples relating to the invention have been described in the foregoing description with reference to the accompanying drawings. However, the above description and drawings are illustrative only. The invention is not limited to the illustrated implementations, embodiments, and/or examples, and all implementations, embodiments, and/or examples of the invention need not necessarily achieve every advantage or purpose, or possess every characteristic, identified herein. Accordingly, various changes, modifications, or omissions may be effected by one skilled in the art without departing from the scope or spirit of the invention, which is limited only by the appended claims. Although example materials and dimensions have been provided, the invention is not limited to such materials or dimensions unless specifically required by the language of a claim. Elements and uses of the above-described implementations, embodiments, and/or examples can be rearranged and combined in manners other than specifically described above, with any and all permutations within the scope of the invention, as limited only by the appended claims.

In the claims, various portions may be prefaced with letter or number references for convenience. However, use of such references does not imply a temporal or ordered relationship not otherwise required by the language of the claims. Unless the phrase ‘means for’ or ‘step for’ appears in a particular claim or claim limitation, such claim or claim limitation should not be interpreted to invoke 35 U.S.C. § 112 (f).

As used herein, satisfying a threshold may, depending on the context, refer to a value being greater than the threshold, greater than or equal to the threshold, less than the threshold, less than or equal to the threshold, equal to the threshold, and/or the like, depending on the context.

As used in the specification and in the claims, use of “and” to join elements in a list forms a group of all elements of the list. For example, a list described as comprising A, B, and C defines a list that includes A, includes B, and includes C. As used in the specification and in the claims, use of “or” to join elements in a list forms a group of at least one element of the list. For example, a list described as comprising A, B, or C defines a list that may include A, may include B, may include C, may include any subset of A, B, and C, or may include A, B, and C. Unless otherwise stated, lists herein are inclusive, that is, lists are not limited to the stated elements and may be combined with other elements not specifically stated in a list. As used in the specification and in the claims, the singular form of ‘a’, ‘an’, and ‘the’ include plural referents (e.g., one or more of the referent) unless the context clearly dictates otherwise.

It is to be expressly understood that the drawings are for the purpose of illustration and description only and are not intended as a definition of the limits of the invention.

It is to be expressly understood that the drawings are for the purpose of illustration and description only and are not intended as a definition of the limits of the invention.

Unless otherwise stated, any range of values disclosed herein sets out a lower limit value and an upper limit value, and such ranges include all values and ranges between and including the limit values of the stated range, and all values and ranges substantially within the stated range as defined by the order of magnitude of the stated range.

The inventors hereby state their intent to rely on the Doctrine of Equivalents to determine and assess the reasonably fair scope of their invention as pertains to any apparatus not materially departing from but outside the literal scope of the invention as set out in the following claims.

What is claimed is:

1. A socket system, comprising:
a housing including:
a base configured to receive a printed circuit board having a multitude of electrical contacts on a first side of the printed circuit board such that a second side of the printed circuit board is disposed on the base, wherein the second side of the printed circuit board is parallel to the first side of the printed circuit board, wherein the printed circuit board includes a plurality of header pins configured to electrically connect the printed circuit board to an electrical testing device or a programming device, wherein the base is configured for attachment to the electrical testing device or the programming device, respectively; and
an alignment component integral with the base;
a clamp including:
a rigid cover hingedly attached to the base and configured to rotate about the hinged attachment between a closed position of the clamp and an open position of the clamp; and
a soft block disposed on the rigid cover;
a soft partially-conductive substrate configured to be disposed on the first side of the printed circuit board such that the electrical contacts are covered by the soft partially-conductive substrate, wherein the soft partially-conductive substrate includes a grid of conductive filaments in a substrate of soft non-conductive material; and
wherein:
the soft block is configured to apply a compressive force to a chip disposed on the soft partially-conductive substrate when the clamp is in the closed position of the clamp; and
when the clamp is in the closed position, a portion of the chip is abutted to the alignment component.

2. The socket system of claim 1, wherein the alignment component and the base are monolithic.

3. The socket system of claim 1, wherein the header pins are configured to electrically connect the printed circuit board to the electrical testing device or the programming device, respectively, via a cable.

4. The socket system of claim 1, wherein the soft block comprises rubber or foam.

5. A socket system, comprising:
a housing including:
a base configured to receive a printed circuit board having a multitude of electrical contacts on a first side of the printed circuit board such that a second side of the printed circuit board is disposed on the base, wherein the second side of the printed circuit board is parallel to the first side of the printed circuit board;
a clamp including:
a rigid cover hingedly attached to the base and configured to rotate about the hinged attachment between a closed position of the clamp and an open position of the clamp; and
a soft block disposed on the rigid cover;
a soft partially-conductive substrate configured to be disposed on the first side of the printed circuit board such that the electrical contacts are covered by the soft partially-conductive substrate, wherein the soft partially-conductive substrate includes a grid of conductive filaments in a substrate of soft non-conductive material; and
wherein the soft block is configured to apply a compressive force to a chip disposed on the soft partially-conductive substrate when the clamp is in the closed position of the clamp.

6. The socket system of claim 1, wherein the housing further includes an alignment component integral with the base.

7. The socket system of claim 6, wherein the alignment component and the base are monolithic.

8. The socket system of claim 6, wherein when the clamp is in the closed position, a portion of the chip is abutted to the alignment component.

9. The socket system of claim 5, wherein the base further comprises a pressure sensor configured to sense a chip pressure resultant from the compressive force imparted thereon when the clamp is in the closed position of the clamp.

10. The socket system of claim 5, wherein the socket system further comprises a camera configured to image the chip disposed on the soft partially-conductive substrate.

11. The socket system of claim 5, wherein the printed circuit board includes a plurality of header pins configured to electrically connect the printed circuit board to an electrical testing device or a programming device.

12. The socket system of claim 11, wherein the header pins are configured to electrically connect the printed circuit board to the electrical testing device or the programming device, respectively, via a cable.

13. The socket system of claim 5, wherein the soft block comprises rubber or foam.

14. The socket system of claim 5, wherein the base is configured for attachment to an electrical testing device or a programming device.

15. The socket system of claim 5, wherein the base is configured for mounting to a motherboard.

16. A method, comprising:
providing a socket system, comprising:
a housing including:
a base configured to receive a printed circuit board having a multitude of electrical contacts on a first side of the printed circuit board such that a second side of the printed circuit board is disposed on the base, wherein the second side of the printed circuit board is parallel to the first side of the printed circuit board; and
an alignment component integral with the base;
a clamp including:
a rigid cover hingedly attached to the base and configured to rotate about the hinged attachment between a closed position of the clamp and an open position of the clamp; and
a soft block comprising rubber or foam an disposed on the rigid cover;
a soft partially-conductive substrate configured to be disposed on the first side of the printed circuit board such that the electrical contacts are covered by the soft partially-conductive substrate; and
placing a chip on the soft partially-conductive substrate;
closing the clamp, thereby by the soft block applying a compressive force to the chip.

17. The method of claim 16, further comprising determining an orientation of the chip relative to the printed circuit board.

18. The method of claim 16, further comprising testing the chip.

19. The method of claim 16, further comprising electrically connecting a plurality of header pins of the printed circuit board to an electrical testing device or a programming device.

20. The method of claim 19, wherein the header pins are electrically connected to the electrical testing device or the programming device, respectively, via a cable.
